(19) United States
(12) Patent Application Publication
(10) Pub. No.: US 2026/0068673 A1
(43) Pub. Date: Mar. 5, 2026

(54) MULTI-JET LIQUID IMPINGEMENT MANIFOLD SYSTEM FOR ON-CHIP COOLING

(71) Applicant: Purdue Research Foundation, West Lafayette, IN (US)

(72) Inventors: Tiwei Wei, Lafayette, IN (US); Gopinath Sahu, West Lafayette, IN (US)

(73) Assignee: Purdue Research Foundation, West Lafayette, IN (US)

(21) Appl. No.: 19/304,541

(22) Filed: Aug. 19, 2025

Related U.S. Application Data
(60) Provisional application No. 63/687,738, filed on Aug. 27, 2024.

(51) Int. Cl. H01L 23/473

(52) U.S. Cl. CPC H01L 23/4735

(57) ABSTRACT

A multi-jet liquid impingement cooler for on-chip cooling is disclosed, providing an ultra-thin, compact solution for high-power electronic devices. The cooler comprises a manifold having an integrated serpentine wall structure, and laterally alternating feeding and draining nozzles. The integrated serpentine wall structure separates cool and heated coolant flow channels. The feeding nozzles direct, in jets, a cool coolant, which is delivered to the manifold, toward the electronic device for impingement cooling, and the draining nozzles remove the heated coolant from the manifold.

### CROSS-REFERENCE TO RELATED APPLICATIONS

This application claims priority to, and the benefit of, U.S. Provisional Ser. No. 63/687,738 , filed on Aug. 27, 2024, the entirety of which is incorporated herein by reference.

### TECHNICAL FIELD

The present application relates generally to thermal management systems for high-power electronics, and, more particularly, to an ultra-thin liquid jet impingement cooler with a serpentine manifold for efficient heat dissipation in compact electronic devices.

### BACKGROUND

Cooling demands of contemporary high-power electronic devices are rapidly increasing due to the further downsizing of components with increasing power density. Traditional cooling methods, including air and liquid cooling with thermal interface materials (TIMs), face limitations in stack-up height, and thermal resistance. The thermal design power of server central processing units (CPUs) is increasingly reaching over 400 W. Furthermore, the next generation of 1U chassis for data centers is limited to a height of 1.75 inches (44.45 mm), restricting the vertical space for cooler design. Other applications also feature design constraints, including high-power light emitting diodes (LEDs), power electronics, battery thermal management, and engines. The integrated heat spreader is a vital thermal management component that improves the heat dissipation efficiency of semiconductor devices, ensuring their stable operation and longevity by maintaining lower operating temperatures.

The heat flux demands for several electronics exceed 100 W/cm², while reliable operating temperature limit is ˜80° C. Passive cooling is no longer a feasible solution to dissipate the required thermal loads. Efficient cooling systems for high power electronics may incorporate thermal management solutions such as micro-channels, liquid jets, and vapor chambers. These methods enhance heat dissipation, achieving chip-to-sink thermal resistance values of less than 0.2° C./W. Two-phase operations to utilize latent heat still possess several challenges, including the separation of liquid and vapor flow, hydrodynamic instabilities, and higher pressure drops. Among active cooling techniques in single-phase operations, liquid jet impingement has gained traction in recent years owing to high heat transfer rates at a relatively low-pressure drop and a possibility for compact product packaging. However, existing designs suffer from poor flow uniformity, high pressure drops, or require excessive height, complex geometries and additional chambers to manage fluid routing.

Therefore, there is a need for an integrated, low-profile cooler that maintains performance while minimizing footprint.

### SUMMARY

Described herein is a technical solution for cooling microelectronic devices, which provides an ultra-thin and compact, laterally fed, serpentine manifold system with integrated jet impingement features that eliminate the need for intermediate TIMs, reduce overall height, and maintain low thermal resistance even under high heat flux loads.

In one aspect of the described embodiments, a system is provided, which can comprise: a manifold configured to be thermally coupled to an electronic device; a plurality of inlet nozzles; a plurality of outlet nozzles; and at least one partition wall defining a serpentine working fluid flow path in the manifold. The inlet nozzles can be configured to direct in jets a working fluid delivered to the manifold for impingement cooling of the electronic device. The outlet nozzles can be configured to remove a heated working fluid from the manifold. The inlet nozzles and the outlet nozzles can be arranged in a lateral alternating pattern. The system can further comprise at least one inlet flow channel and at least one outlet flow channel separated by the at least one partition wall. The at least one inlet flow channel and the at least one outlet flow channel can be alternately arranged across the width of the manifold. The inlet nozzles can be fluidly connected to the at least one inlet flow channel, and the outlet nozzles can be fluidly connected to the at least one outlet flow channel. The inlet nozzles can be arranged perpendicularly to the at least one inlet flow channel, and the outlet nozzles can be arranged perpendicularly to the at least one outlet flow channel. The inlet nozzles and the outlet nozzles can be arranged in a staggered pattern across the width of the manifold. The system can further comprise one or more inlets for delivering the working fluid into the manifold and one or more outlets for removing the heated working fluid from the manifold. The one or more inlets can be fluidly connected to the inlet nozzles, and the one or more outlets can be fluidly connected to the outlet nozzles. The manifold can be assembled with the electronic device in a stacked assembly comprising a substrate, the electronic device supported on the substrate, and the manifold attached to or integrated in a lid attached to the substrate, such that a heat transfer area of the manifold interfaces with a heat-generating surface of the electronic device. The manifold can have a total height of 5 mm or less. The size of each inlet nozzle can be similar/smaller than the size of each outlet nozzle. The working fluid can be a coolant selected from water and a dielectric working fluid. The system can be configured to be attached to the electronic device without intermediate thermal interface materials, by direct interfacing of the heat transfer area of the manifold with the electronic device.

In another aspect of the described embodiments, a method of cooling an electronic device is provided, where a manifold is used that is configured to be thermally coupled to the electronic device by a heat transfer area of the manifold. The heat transfer area of the manifold can comprise inlet nozzles and outlet nozzles laterally arranged in an alternating pattern, and at least one partition wall defining a serpentine flow path with separated cool and heated coolant flow channels. The method can comprise positioning the manifold over the electronic device, introducing the coolant through the inlet nozzles to create impinging coolant jets directed towards the electronic device for cooling the electronic device, collecting a heated coolant through the outlet nozzles, and maintaining a surface temperature of the electronic device below 80° C. under operating heat flux conditions. The coolant can be delivered to the manifold through at least one inlet fluidly connected to the inlet nozzles, and the heated coolant can be removed from the manifold through at least one outlet fluidly connected to the outlet nozzles. The method can further comprise controlling a coolant flow rate between 0.5 LPM and 2.5 LPM. In the method, the manifold can be attached to the electronic device without intermediate thermal interface materials by direct interfacing with the electronic device.

In one more aspect of the described embodiments, a multi-jet liquid impingement cooler for microelectronic devices is provided, which can comprise a manifold having an integrated serpentine wall structure, and alternating feeding and draining nozzles. The integrated serpentine wall structure can separate cool and heated coolant flow channels. The feeding nozzles can be configured to direct a cool coolant (which is delivered to the manifold) in jets toward the microelectronic device for impingement cooling of the microelectronic device. The draining nozzles can be configured to remove the heated coolant from the manifold.

This summary is provided to introduce a selection of the concepts that are described in further detail in the detailed description and drawings contained herein. This summary is not intended to identify any primary or essential features of the claimed subject matter. Some or all of the described features may be present in the corresponding independent or dependent claims but should not be construed to be a limitation unless expressly recited in a particular claim. Each embodiment described herein does not necessarily address every object described herein, and each embodiment does not necessarily include each feature described. Other forms, embodiments, objects, advantages, benefits, features, and aspects of the present disclosure will become apparent to one of skill in the art from the detailed description and drawings contained herein. Moreover, the various systems and methods described in this summary section, as well as elsewhere in this application, can be expressed as a large number of different combinations and sub-combinations. All such useful, novel, and inventive combinations and sub-combinations are contemplated herein, it being recognized that the explicit expression of each of these combinations is unnecessary.

### BRIEF DESCRIPTION OF THE DRAWINGS

While the specification concludes with claims which particularly point out and distinctly claim this technology, it is believed this technology will be better understood from the following description of certain examples taken in conjunction with the accompanying drawings, in which like reference numerals identify the same elements and in which:

FIG. 1 is a schematic lateral cross-sectional view of a prior art liquid cooling-based solution for thermal management of high-power chips, which comprises a chip assembly with a cold plate on a lid.

FIG. 2 is a schematic lateral cross-sectional view of another prior art liquid cooling-based solution for thermal management of high-power chips, which comprises a chip assembly with a micro-channel heat spreader.

FIG. 3A is a schematic lateral cross-sectional view of a liquid cooling-based solution for thermal management of high-power chips in accordance with the present disclosure, which comprises a chip assembly with a lid-integrated liquid jet impingement cooler having a lateral feeding manifold with serpentine design and alternating feeding and draining multiple jets.

FIG. 3B is a schematic top cross-sectional view of fragment A as shown in FIG. 3.

FIG. 4 shows schematic top and lateral cross-sectional views of the lateral feeding manifold, particularly illustrating inlet and outlet plenums and a total plenum height of the manifold.

FIG. 5 is a schematic representation of distributed liquid jets impingement in the manifold of the cooler in accordance with the present disclosure.

FIG. 6 is a general view of an exemplary 3D printed cooler in accordance with the present disclosure, with internal structure shown.

FIG. 7 shows design details of the 3D printed cooler of FIG. 5, including dimensions and internal structure.

FIG. 8 is a schematic representation of an experimental setup used for hydrodynamic and thermal performance of the manifold on accordance with the present disclosure for various load and flow rate conditions.

FIG. 9A schematically shows geometry and boundary conditions used for numerical simulation of a unit cell of the manifold model in accordance with the disclosure.

FIG. 9B schematically shows geometry and boundary conditions used for numerical simulation of a full-scale manifold model in accordance with the disclosure.

FIG. 10 is a chart showing effect of the coolant flow rate on the pressure drop.

FIG. 11A is a chart showing effect of increasing coolant flow rate with the thermal resistance for various heat flux boundary conditions.

FIG. 11B is a chart showing comparison of overall performance through normalized resistance and pumping power of the cooler in accordance with the disclosure, with literatures.

FIG. 12A is a chart showing steady state temperature for various flow rate and heat flux conditions for the cooler in accordance with the disclosure.

FIG. 12B is a chart showing heat transfer coefficient for various flow rate and heat flux conditions for the cooler in accordance with the disclosure.

FIG. 13 is a chart showing comparison of numerically obtained surface temperature with experiments for both unit cell model of FIG. 9A and full-scale manifold model of FIG. 9B of the cooler in accordance with the disclosure.

FIG. 14 shows flow and mal-distribution within the manifold across inlets and outlets of the manifold in percentage.

FIG. 15 shows surface temperature non-uniformity noticed over impinging surface for a heat flux of 200 W/cm² and flow rate of 2.5 LPM for the manifold in accordance with the disclosure.

FIG. 16 shows surface temperature non-uniformity for the manifold, where inlets and outlets are interchanged.

FIG. 17 shows (a) a schematic representation, and (b) image of NVIDIA V100 chip showing logic and HBM, and (c) compact manifold cooler in accordance with a particular embodiment of the present disclosure with dimensions and internal cross-plane structure.

FIG. 18 shows steps of a method of integration of the cooler in accordance with a particular embodiment of the present disclosure with the V100 chip and its mounting onto a server.

FIG. 19 shows charts of thermal performance characterization of the manifold design shown in FIGS. 17-18 using (a) steady-state temperature, (b) thermal resistance, (c) exit vapor quality, (d) pressure drop across the manifold for various power level and coolant flow rates.

FIG. 20 shows (a) GPU power map and (b) temperature map during transient response study for a flow rate of 0.5 LPM for the compact manifold cooler assembly as shown in FIGS. 17-18.

FIG. 21 shows a chart with thermo-hydraulic performance comparison by evaluating the normalized thermal resistance and pumping power of the manifold cooler shown in FIGS. 17-18 using the dielectric refrigerant R1233zd(E), benchmarked against literature data based on water as the working fluid.

The drawings are not intended to be limiting in any way, and it is contemplated that various embodiments of the technology may be carried out in a variety of other ways, including those not necessarily depicted in the drawings. The accompanying drawings incorporated in and forming a part of the specification illustrate several aspects of the present technology, and together with the description serve to explain the principles of the technology; it being understood, however, that this technology is not limited to the precise arrangements shown, or the precise experimental arrangements used to arrive at the various graphical results shown in the drawings.

### DETAILED DESCRIPTION

The following description of certain examples of the technology should not be used to limit its scope. Other examples, features, aspects, embodiments, and advantages of the technology will become apparent to those skilled in the art from the following description, which is by way of illustration, one of the best modes contemplated for carrying out the technology. As will be realized, the technology described herein is capable of other different and obvious aspects, all without departing from the technology. Accordingly, the drawings and descriptions should be regarded as illustrative in nature and not restrictive.

It is further understood that any one or more of the teachings, expressions, embodiments, examples, etc. described herein may be combined with any one or more of the other teachings, expressions, embodiments, examples, etc. that are described herein. The following described teachings, expressions, embodiments, examples, etc., should, therefore, not be viewed in isolation relative to each other. Various suitable ways in which the teachings herein may be combined will be readily apparent to those of ordinary skill in the art in view of the teachings herein. Such modifications and variations are intended to be included within the scope of the claims.

The design requirement for manifolds as an integrated heat spreader in modern electronics cooling systems is developing due to the growing demand for compact and efficient solutions. The cooling technical solution of the present invention represents an advancement over conventional thermal management systems for high-power electronics, as clearly illustrated through the comparative figures.

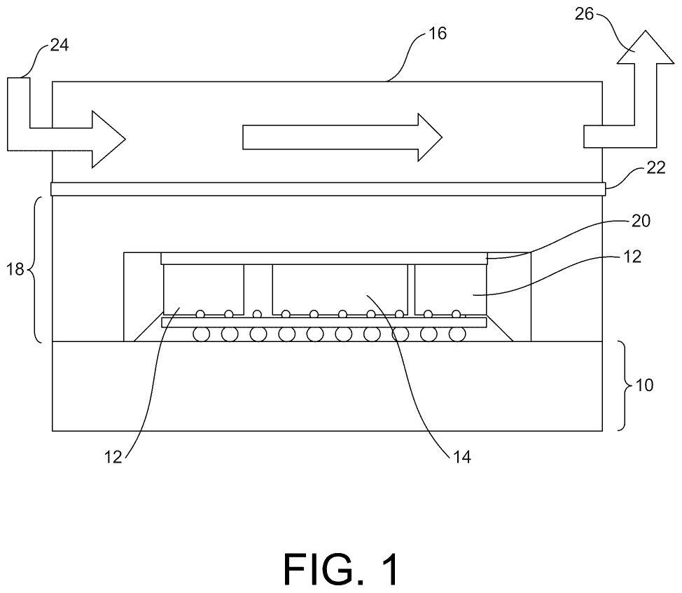

Some of the traditional cooling solutions, as exemplified in FIG. 1, employ a stacked assembly comprising a substrate 10 supporting high-bandwidth memory modules (HBMs) 12 and a system-on-chip (SoC) 14, with a liquid cold plate 16 mounted above a lid 18. The chip components including the HBMs 12 and SoC 14 contact the lid 18 via a TIM 20. The liquid cold plate 16 is mounted above the lid 18 through a second TIM 22 and has a horizontally directed heat removal design from an inlet 24 to the outlet 26, as shown by arrows in FIG. 1. This conventional approach suffers from inherent limitations including thermal resistance at interface layers and excessive vertical height unsuitable for modern compact electronics enclosures.

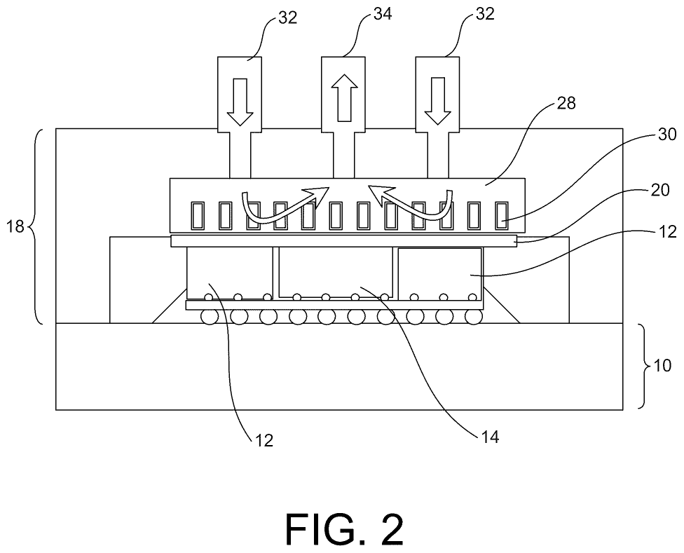

FIG. 2 demonstrates an improved but still problematic prior art chip assembly configuration with micro-channel heat spreader 28 with integrated horizontal microchannels 30 and laterally positioned inlet ports 32 and outlet ports 34, to provide liquid cooling to the SoC 14 and HBMs 12 supported on the substrate 10. In this solution, the chip components including the HBMs 12 and SoC 14 contact the heat spreader 28 via the TIM 20, while the heat spreader 28 is integrated in the lid 18. While this solution represents progress over simple cold plate designs, the microchannel implementation requires complex fabrication processes and exhibits non-uniform flow distribution that can lead to localized hotspots. The inlet and outlet ports 32, 34 further add to the overall system complexity and space requirements.

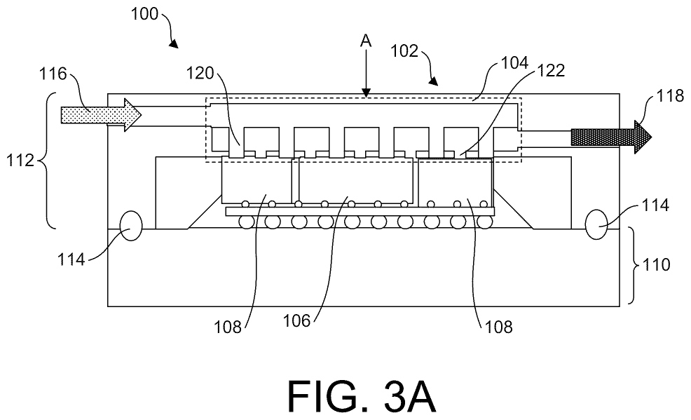

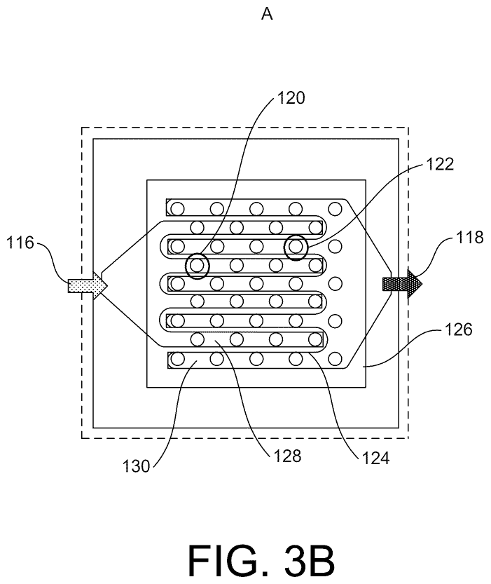

The present invention overcomes these limitations through the electronics cooling system design as shown in FIGS. 3A-5.

FIG. 3A provides a schematic lateral cross-sectional view of an assembly 100 of an electronic device with a multi-jet liquid impingement cooler 102 in accordance with one of the embodiments of the present disclosure. In this assembly, the chip is illustrated as a particular example of the electronic device, which however, in other embodiments, can be replaced by another electronic device having a heat-generating area and requiring cooling. The cooler 102 in accordance with the present disclosure is suitable for cooling various electronic devices such as high-power microelectronic devices, CPUs, high-power LEDs, power electronics, etc.

As shown in FIG. 3A, the cooler 102 comprises a manifold 104 thermally coupled to the electronic device (a chip comprising a SoC 106 and HBMs 108) supported on a substrate 110. In some embodiments, the manifold 104 can be assembled with the electronic device without TIMs by directly interfacing with a surface of the electronic device. In some embodiments, the cooler 102 can be attached to the electronic device as a component, integrated in a lid (enclosure) 112, as particularly illustrated in FIG. 3A. In other embodiments, the cooler 102 can be attached to or covered by the lid 112. The lid 112 can be sealed to the substrate 110 by a sealant 114.

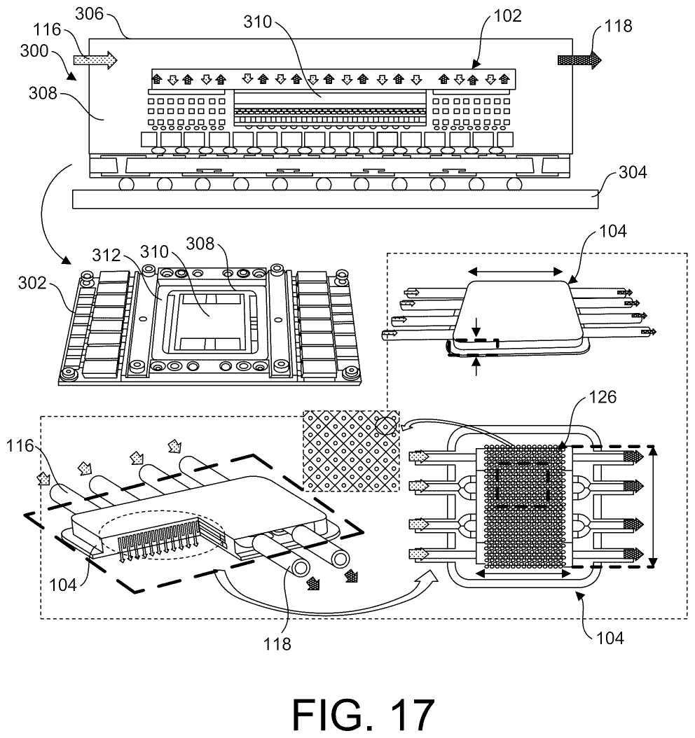

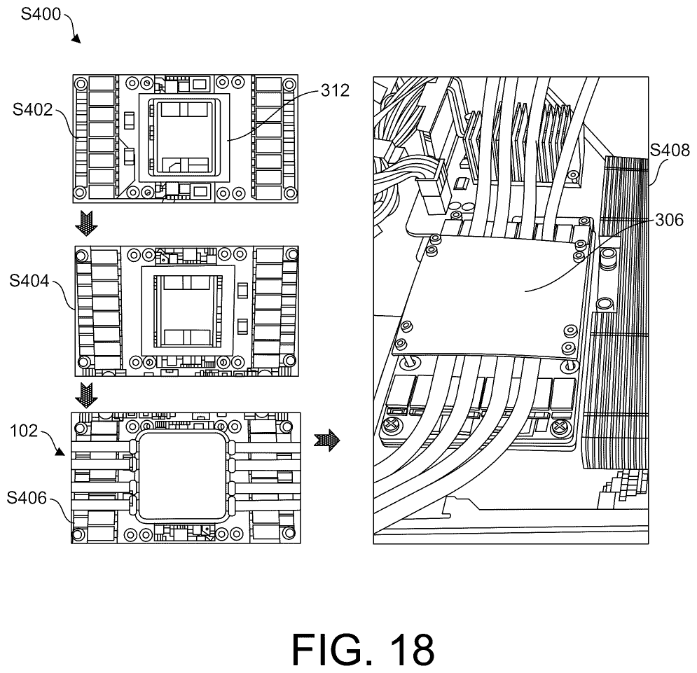

The cooler 102 features single-phase operation with a horizontal liquid feeding and can comprise at least one inlet 116 for delivering a cool liquid (working fluid) into the manifold 104 and at least one outlet 118 for removing a heated working fluid from the manifold 104. In some embodiments, the cooler 102 can comprise a plurality of inlets 116 and a plurality of outlets 118, as exemplified in a particular embodiment shown in FIGS. 17 and 18, to increase heat transfer capabilities of the cooler 102. The number of inlets 116 preferably equals or lesser to the number of outlets 118.

The manifold 104 incorporates a plurality of inlet (feeding) nozzles 120 and outlet (draining) nozzles 122 laterally arranged in an alternative pattern. The inlet nozzles 120 are configured to direct a cool working fluid in jets toward the electronic device for impingement cooling, and the outlet nozzles 122 are configured to collect a heated working fluid for removal from the manifold 104. The manifold 104 further comprises at least one partition wall 124 (which is better shown in FIG. 3B) defining a serpentine flow path, to maintain distinct cool and heated working fluid flows.

FIG. 3B presents a detailed top cross-sectional view of the manifold 104 (fragment A as shown in FIG. 3A) revealing a serpentine structure formed by the at least one partition wall 124 and the inlet and outlet nozzles 120, 122 in the manifold 104. The at least one partition wall 124 preferably is integrally internally provided in the manifold 104. A part of the manifold 104, which incorporates the serpentine structure, is referred to herein as a base, or a heat transfer area 126 of the manifold 104. Due to the serpentine structure, the heat transfer area 126 is thermally coupled to the electronic device.

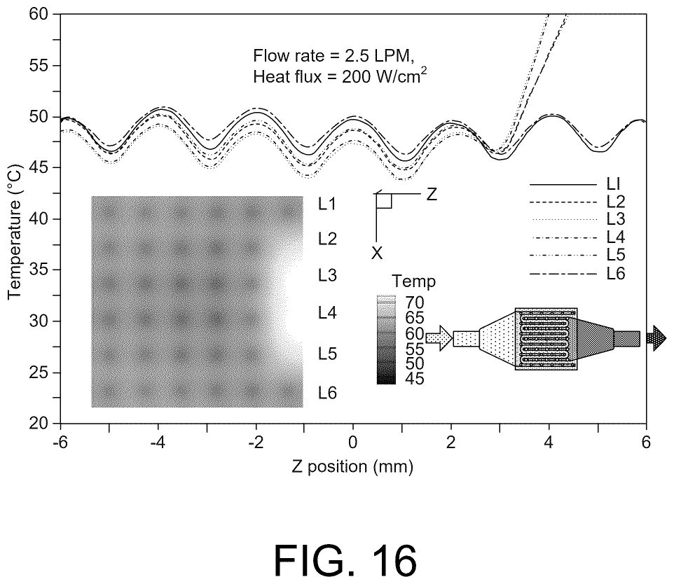

At least one inlet flow channel 128 and at least one outlet flow channel 130 can be formed by the at least one partition wall 124 such that the channels 128, 130 are horizontally distributed across a width of the manifold base 126 and separated from each other by the at least one vertical internal partition wall 124. In some embodiments, due to serpentine design, the number of inlet flow channels 128 can be one channel less than the number of outlet flow channels 130. In a particular embodiment shown in FIG. 3B, the manifold 104 comprises four inlet flow channels 128 and five outlet flow channels 130. In alternative embodiments, the number of inlet flow channels 128 can be one channel more than the number of outlet flow channels 130 (for example, five inlet flow channels 128 and four outlet flow channels 130, as particularly illustrated in the embodiment presented in FIG. 16). The inlet flow channels 128 and the outlet flow channels 130 can be arranged in an alternating pattern across the width of the manifold 104. In some embodiments, the channels 128, 130 are arranged in parallel to each other.

As shown in FIG. 3B, the at least one inlet flow channel 128 is fluidly connected to the at least one inlet 116 and the at least one outlet flow channel 130 is fluidly connected to the at least one outlet 118. The plurality of inlet nozzles 120 is fluidly connected to the at least one inlet flow channel 128, and the plurality of outlet nozzles 122 is fluidly connected to the at least one outlet flow channel 130. In some embodiments, the plurality of inlet nozzles 120 are perpendicular to the horizontally arranged at least one inlet flow channel 128, and the plurality of outlet nozzles 122 are perpendicular to the horizontally arranged at least one outlet flow channel 130. In some embodiments, the inlet nozzles 120 and the outlet nozzles 122 form a staggered pattern in the heat transfer area 126 across the width of the manifold 104.

Due to the specific multi-jet serpentine manifold configuration of the cooler 102, the entire assembly 100 achieves a compact design with a remarkably low profile.

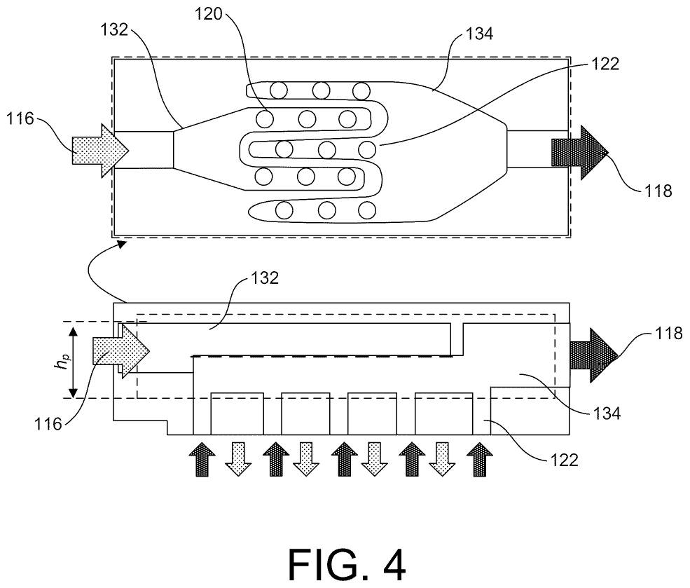

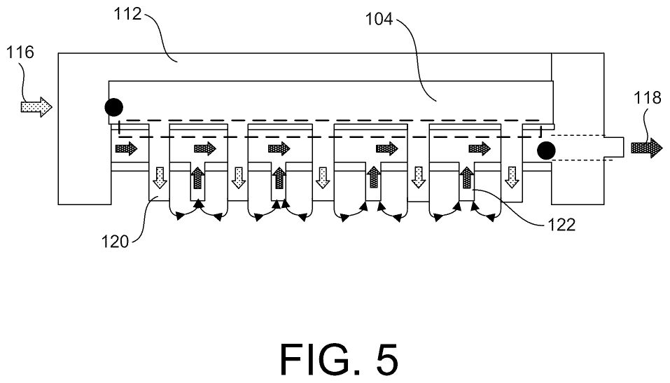

FIGS. 4 and 5 show a schematic representation of a flow path architecture of the manifold 104. FIG. 4 particularly illustrates inlet plenum 132 and outlet plenum 134 of the manifold 104. The inlet plenum 132 and the outlet plenum 134 of the manifold 104 are in the same plane due to the serpentine design, achieving a total plenum height hₚ, which is much less compared to the prior art conventional solutions mentioned with reference to FIGS. 1 and 2. In some embodiments, the total inlet and outlet plenum height hₚ in the manifold 104 is less than 5 mm. This dimension highlights the compactness of the manifold 104 for integration into space-constrained environments such as 1U servers. The alternating inlet nozzles 120 and outlet nozzles 122 are arranged to ensure balanced flow distribution across the entire heated surface, preventing stagnation zones and optimizing heat extraction.

FIG. 5 illustrates a distributed multi-jet liquid impingement approach implemented in the cooler 102 according to the present disclosure, which achieves enhanced cooling performance through optimized fluid dynamics and thermal transfer principles. The array of micro-orifice nozzles 120, 122 arranged in a lateral alternating pattern and across the entire heat transfer area serve as the primary impingement sites, delivering high-velocity jets of a cooling working fluid (shown by arrows in FIG. 5) directly onto heat-generating surfaces of the electronic device. Each inlet nozzle 120 connects to a dedicated inlet flow channel 128 (as shown in FIG. 3B), which originates from the main inlet plenum 132, ensuring uniform flow distribution across all jet sites and maintaining constant fluid velocity despite pressure variations.

Laterally, between each impingement nozzle (i.e. inlet nozzle 120), the design incorporates drainage ports (i.e. outlet nozzles 122) that form an interlocking network of return channels. These drainage nozzles 122 serve the dual function of efficiently removing heated cooling working fluid while creating controlled cross-flow patterns that enhance thermal mixing. The drainage network feeds into a common outlet plenum 134 that runs parallel to the inlet distribution structure, maintaining separation between incoming and outgoing fluid streams through the integrated partition wall structure 124. The manifold's thermal performance is further enhanced by staggered nozzle positioning across the width of the manifold 104, which prevents hydraulic boundary layer buildup. This zoned cooling approach matches the non-uniform power distribution typical of advanced processor architectures.

In some embodiments, the cooling working fluid used in the cooler 102 can be selected from a coolant such as water and a dielectric fluid, among which the dielectric fluid can be preferable. The example of dielectric working fluid is R1233zd(E).

In some embodiments, the cooler 102 according to the present disclosure can be additively manufactured (e.g., 3D printed).

### EXAMPLE 1

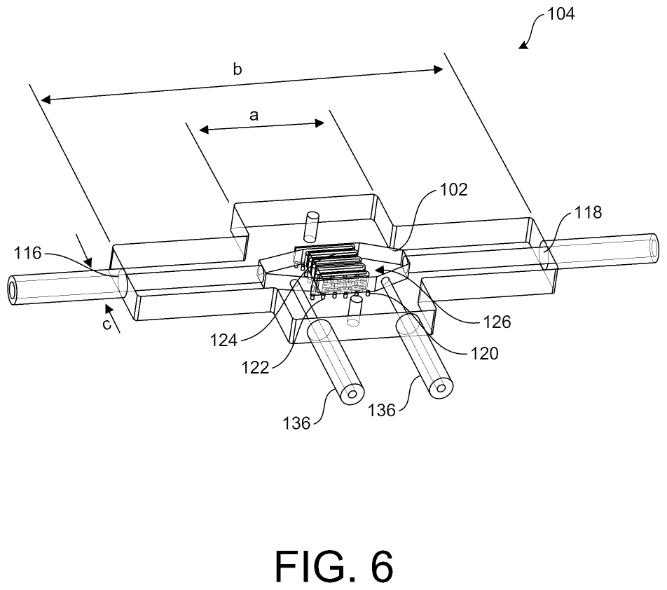

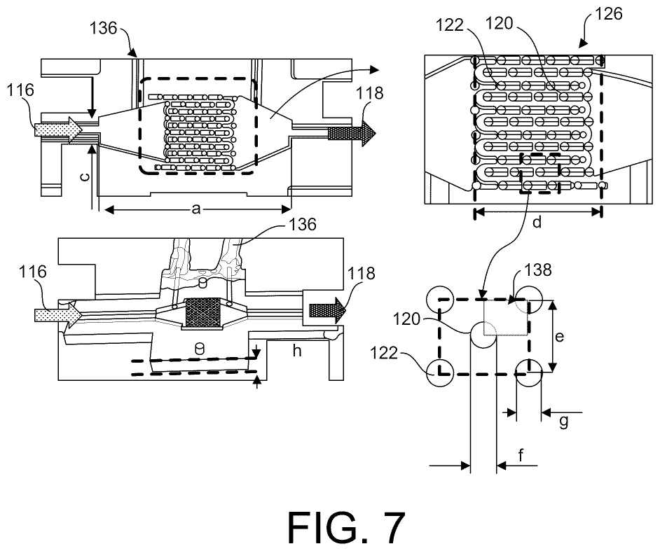

FIGS. 6-7 illustrate an example of a 3D printed cooler 102, which can be manufactured according to the present disclosure. The 3D printed cooler 102 illustrated in FIGS. 6-7 is designed for chip-level liquid jet impingement over a heated surface.

FIG. 6 particularly shows a general view of the 3D printed cooler 102. The 3D printed cooler 102 comprises one inlet 116 in the form of an inlet tube and one outlet 118 in the form of an outlet tube. The inlet and outlet tubes expand closer to the base 126 of the manifold 104 to form the inlet plenum 132 and the outlet plenum 134 connecting to the corresponding inlet flow channels 128 and outlet flow channels 130 separated by the serpentine partition wall 124 integrally formed in the manifold 104 in the area of the base 126. The inlet and outlet nozzles 120, 122 are arranged perpendicularly to the channels 128, 130 and to the base 126. Two pressure taps 136, inlet and outlet one, are further provided in the cooler 102 to connect to the internal volume of the manifold 104 for regulating pressure.

Referring to FIG. 6, a central portion of the cooler 102 comprising the serpentine structure, inlet plenum 132 and outlet plenum 134, has a length a, and in the exemplary embodiment shown in FIGS. 6-7 this length a is equal to 26 mm. In the exemplary embodiment shown in FIGS. 6-7, the total length b of the cooler 102 between the inlet 116 and the outlet 118 is equal to 76 mm, and a specific diameter c of each of tubes connecting to the inlet 116 and outlet 118 for delivering and removing working fluid respectively is equal to 3 mm.

The other dimensions of the 3D printed cooler 102 are shown in FIG. 7. Particularly, the serpentine structure of the manifold 104 has a length d which is preferably essentially equal to its width. In the exemplary embodiment shown in FIGS. 6-7, the length d is equal to the width and is 10 mm, so that the heat transfer area 126 is sized as 10 mm×10 mm. In this embodiment, the number of inlet nozzles 120 and the number of outlet nozzles 122 in each row is equal to five with six outlet nozzles in the two extreme rows respectively, and the inlet nozzles 120 and outlet nozzles 122 form a staggered pattern across the heat transfer area 126. In the exemplary embodiment shown in FIGS. 6-7, the overall height h of the cooler 102, including the inlet and outlet nozzle feeders 120, 122 is 5 mm.

The staggered pattern formed by the laterally alternating inlet and outlet nozzles can be “divided” into repeating unit cells 138 forming building blocks of the multi-jet serpentine design. The unit cell 138 represents the smallest functionally independent cooling element that can be tessellated across the entire heat transfer area 126, demonstrating the scalability of the same. The size of the unit cell 138 is ½ of the dimension e shown in FIG. 7. In the exemplary embodiment shown in FIGS. 6-7, the size of the unit cell 138 is 1 mm.

Manifolds having sub millimeters scale nozzles have been demonstrated to be more energy efficient. In this exemplary embodiment, the size (diameter) f of the inlet nozzles 120 and the size (diameter) g of the outlet nozzles 122 are kept 0.6 mm and 0.5 mm, respectively.

The experiments were performed with the 3D printed serpentine manifold cooler 102 illustrated in FIGS. 6-7, aiming to investigate the enhancement of thermo-hydraulic performance of the cooler 102 during single phase operations. A novel serpentine manifold 104 is considered to reduce its overall height, which is 5 mm in the example. A wide range of experimental boundary conditions were studied, where heat flux increased up to 300 W/cm² and flow rate varied between 0.5 L/min-2.5 L/min.

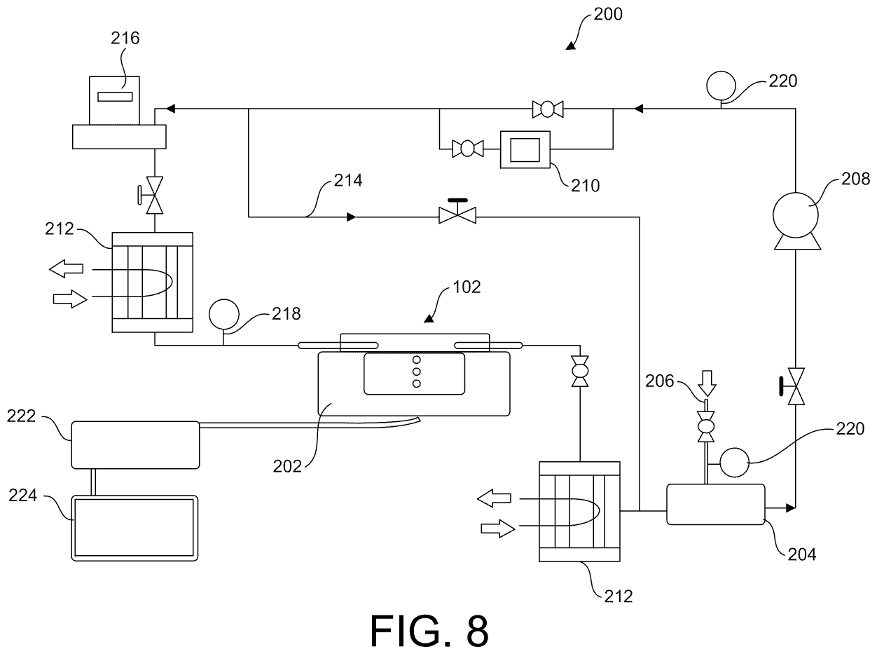

FIG. 8 schematically illustrates an experimental setup 200 developed to measure steady state temperature data for various coolant flow rates and heat flux boundary conditions. Pressure drop across the manifold 104 for various flow rates considered in the experiments was measured to investigate its hydraulic performance.

The experimental setup 200 depicted in FIG. 8 represents a comprehensive flow loop system designed to rigorously evaluate the thermal and hydrodynamic performance of the cooler 102 attached to a heater assembly 202 designed to replicate real-world GPU thermal loads while enabling controlled performance evaluation of the cooling system. The system features a closed-loop configuration where the dielectric coolant R1233zd(E) circulates through several components, each serving specific functions while maintaining operational control.

The experimental setup 200 incorporates a pressurized coolant reservoir 204 designed to maintain stable fluid conditions while enabling comprehensive performance monitoring. The coolant is supplied to the reservoir 204 via a fill port 206. At the heart of the system, a pump 208 drives the coolant through a 2 μm particulate filter 210 that ensures fluid purity before entering a liquid-to-liquid heat exchanger 212. This heat exchanger 212 plays a crucial role in maintaining the coolant at the desired saturation temperature of 37.5° C. with 1° C. of subcooling, establishing consistent thermal boundary conditions for testing. A bypass line 214 running parallel to the main loop provides fine flow rate control, while a flow meter 216 positioned immediately upstream of the test section accurately measures the volumetric flow rate ranging from 0.25 to 1 LPM.

The test section itself consists of the heat assembly 202 serving as the heat source, capable of generating up to 300 W thermal design power through CUDA stress test software. The 3D-printed cooler 102 mounts directly onto the heat assembly 202. The impinging and draining nozzles 120, 122 deliver targeted cooling to both the heat assembly 202.

Instrumentation for performance monitoring includes pressure sensors 218 and temperature sensors 220 positioned at the line to measure pressure drops and coolant temperature differentials, with all data logged in real-time by a centralized DAQ system 222 connected to a computer 224. This integrated setup 200 allows for comprehensive evaluation under controlled conditions, enabling measurement of performance metrics including thermal resistance, pressure drop, and transient response to dynamic power loads. The system's design specifically facilitates investigation of cooling behavior while maintaining operational pressures below 25 kPa, demonstrating the practical viability of this cooling solution for high-power electronic applications.

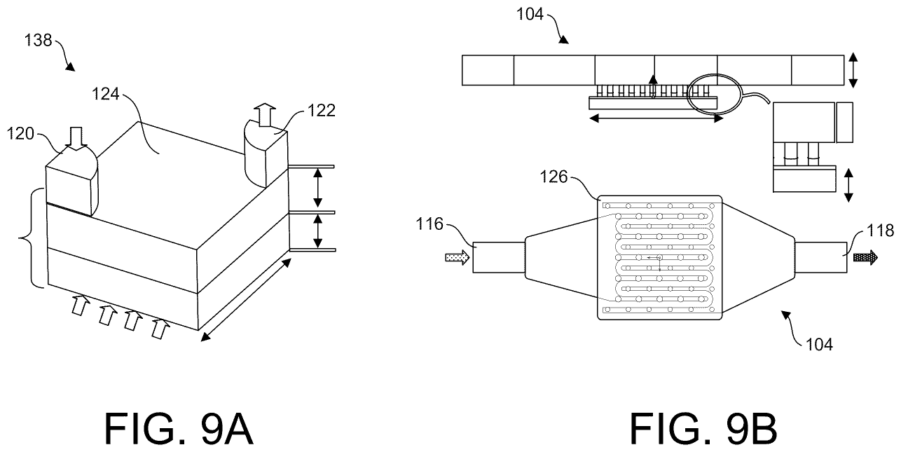

FIGS. 9A and 9B illustrate numerical setup geometry and boundary conditions used for numerical simulation for performing thermos-hydrodynamic analysis. The thermo-hydrodynamic analysis is performed with Ansys Fluent, 2023R2.

FIG. 9A schematically shows geometry and boundary conditions used for numerical simulation of a unit cell 138 of the manifold model illustrated in FIGS. 6-7. Unit cell approach is computationally inexpensive and provides a reasonable estimate of various thermo-hydrodynamics performance. FIG. 9A depicts the unit cell simulation model in the form of a single repeating element 1 mm×1 mm, containing all essential features of the full-scale design. The computational domain includes: (1) a 0.6 mm diameter inlet nozzle 120, (2) a 0.5 mm drainage outlet nozzle 122, and (3) a heated wall surface representing the chip interface with applied heat flux (100-400 W/cm²). The model implements conjugate heat transfer analysis, coupling fluid dynamics with the liquid interface of 0.3 mm and solid heat conduction through the 0.2 mm thick plate. The inlet and outlet nozzles 120, 122 are separated by the insulated wall 124. Symmetry boundary conditions are applied at all vertical faces to simulate infinite array conditions, while the bottom surface incorporates a thermal interface resistance of 0.01 K·cm²/W to represent the die attachment. This unit cell approach enables efficient parametric studies of nozzle geometry variations while maintaining computational tractability.

FIG. 9B expands this methodology to the full-scale manifold simulation of the model illustrated in FIGS. 6-7, capturing system-level thermal-hydraulic behavior. FIG. 9B shows the complete model incorporating 10 mm×10 mm heat transfer area 126 with five inlet flow channels 128 merging into the inlet plenum 132, six outlet flow channels 130 merging into the outlet plenum 134, and 25 inlet nozzles 120, and 32 outlet nozzles 122. The liquid interface under the nozzles 120, 122 is 0.3 mm. The plenum height hₚ is 3 mm. Lateral feeding manifold 104 has inherent disadvantages of flow non-uniformity, which cannot be captured using unit cell model. Therefore, full scale simulation approach is considered for various flow rates to check flow maldistribution and surface temperature non-uniformity.

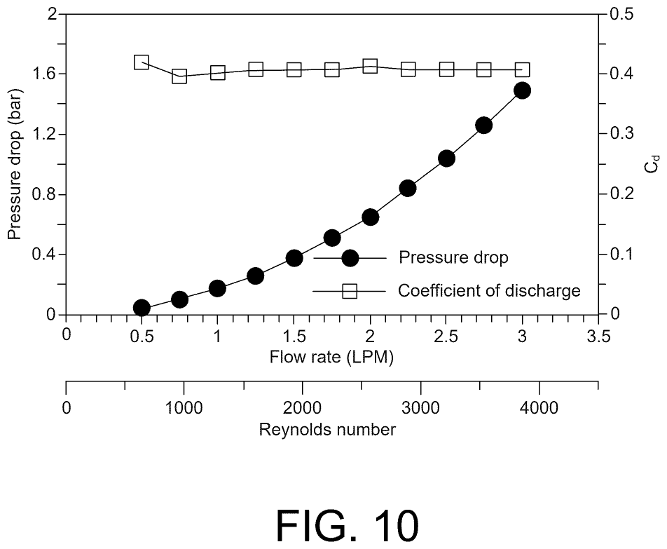

The results of the experiments performed using the experimental setup 200, and the numerical simulation unit cell and full-scale models, are presented in the charts shown in FIGS. 10-15.

FIG. 10 illustrates a hydrodynamic performance of the cooler 102 showing an effect of coolant flow rate on the pressure drop. FIG. 10 particularly illustrates the variation of the pressure drop (bar) across the manifold 104 with respect to the coolant flow rate (LPM). As shown, the pressure drop increases with increasing flow rate due to higher fluid velocities through the inlet and outlet nozzles 120, 122, as well as increased frictional and minor losses within the serpentine channels 128, 130. The relationship demonstrates that the manifold 104 maintains a relatively low-pressure penalty even at the maximum tested flow rate, thereby confirming its suitability for compact, high-performance cooling applications where pumping power is limited.

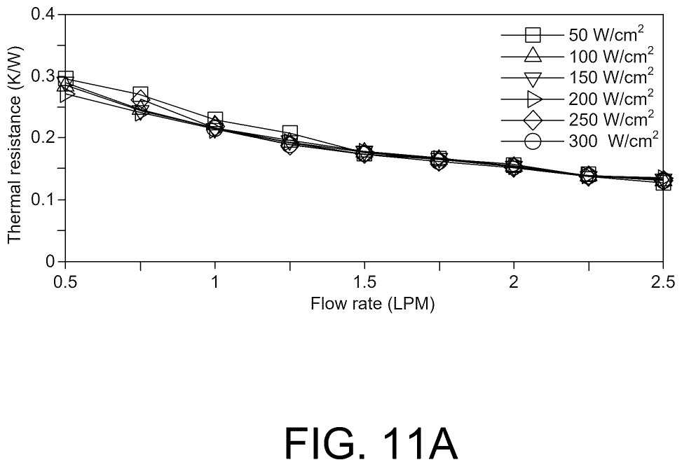

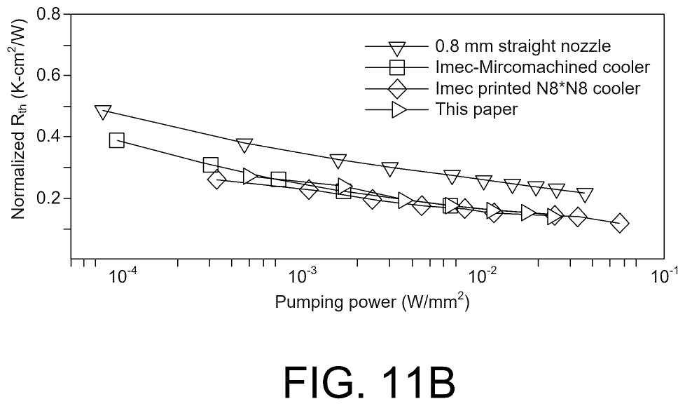

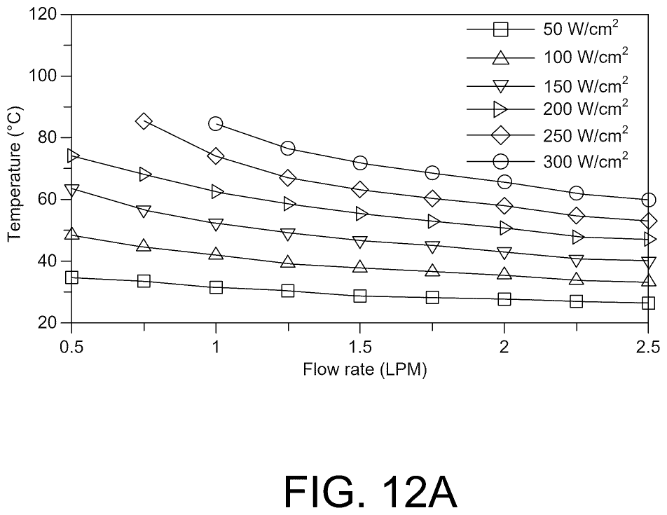

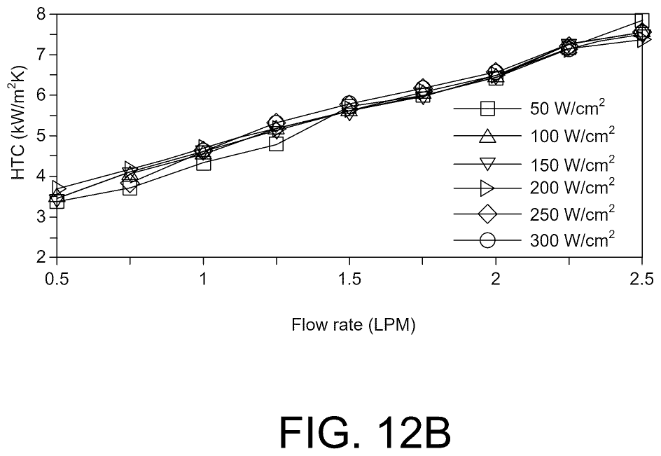

FIGS. 11A-12B illustrate manifold performance in comparison with the known and reported designs.

FIG. 11A presents the effect of increasing coolant flow rate on the thermal resistance of the manifold 104 under different heat flux boundary conditions. Thermal resistance is used to understand the thermal performance of any cooling solutions. It is defined as the ratio of GPU power and the difference between GPU junction temperature and coolant saturation temperature. The curves in FIG. 11A indicate that, for all tested heat fluxes (50, 100, 150, 200, 250, 300 W/cm²), thermal resistance (K/W) decreases markedly as flow rate (LPM) rises, owing to enhanced convective heat transfer from the impinging jets. At higher flow rates, the improvement in thermal resistance becomes less steep, suggesting an approach towards asymptotic limits where further flow increases yield diminishing returns.

FIG. 11B provides a comparative analysis of the overall cooling performance of the disclosed manifold 104 against previously reported designs from literature (0.8 mm straight nozzle, Imec® Micromachined cooler, and Imec® printed N8*N8 cooler). Here, normalized thermal resistance Rₜₕ (K-cm²/W) is plotted against pumping power (W/mm²) to evaluate thermo-hydraulic efficiency. The results show that the disclosed manifold achieves competitive or superior performance in terms of heat removal per unit of pumping power, thereby validating the energy-efficient nature of the serpentine, laterally-fed multi-jet configuration.

FIG. 12A depicts the measured steady-state surface temperature (° C.) of the heated area under various combinations of flow rate (LPM) and applied heat flux (50, 100, 150, 200, 250, 300 W/cm²). The graph confirms that surface temperatures remain well below the operating threshold (80° C.) for all conditions when the coolant flow rate exceeds approximately 0.5-1 LPM, even at a maximum heat flux of 300 W/cm².

FIG. 12B shows the corresponding heat transfer coefficients (HTC, kW/m²K) obtained under the same experimental conditions as FIG. 12A. The HTC increases with coolant flow rate (LPM) due to higher jet Reynolds numbers, and also tends to rise with heat flux as increased temperature differences enhance convective driving forces.

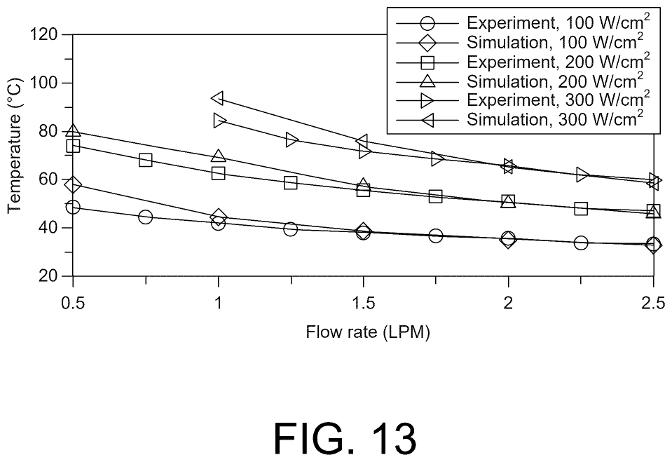

FIGS. 13-15 illustrate flow and surface temperature distribution experimental results.

FIG. 13 compares numerically predicted surface temperatures with experimentally measured values for both the unit cell model (as shown in FIG. 9A) and the full-scale manifold model (as shown in FIG. 9B). The comparison demonstrates close agreement between experimental results and simulations, validating the accuracy of the computational model.

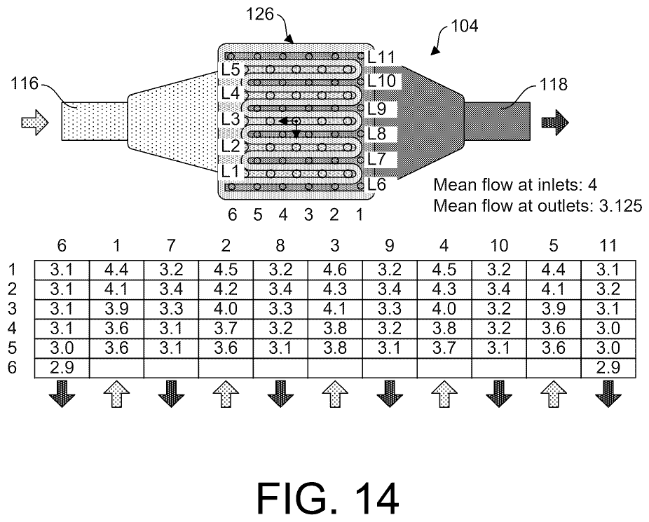

FIG. 14 illustrates the flow maldistribution within the manifold 104 by showing the percentage distribution of coolant flow across different inlet and outlet jets 120, 122 across the channels L1-L11, where the channels numbered L1-L5 are inlet flow channels 128, and the channels numbered L6-L11 are outlet flow channels 130. Each of the channels L1-L5 is connected to five inlet nozzles 120, and each of the channels numbered L7-L10 are connected to five outlet nozzles 120, while each of the two extreme outlet flow channels L6 and L11 is connected to six outlet nozzles 120. The data reveals that certain jets experience higher flow rates than others due to the inherent lateral feeding configuration, which may influence localized cooling performance. However, in overall, the flow rates are rather uniformly distributed, with the mean flow percentage at inlets being equal to 4, and the mean flow percentage at outlets being equal to 3.125.

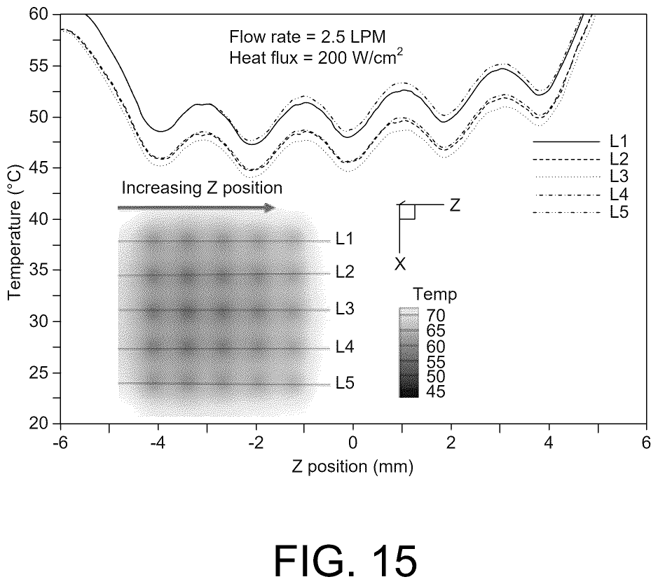

FIG. 15 shows a surface temperature map of the impingement area for a representative operating condition of 200 W/cm² heat flux and 2.5 L/min coolant flow rate. While the overall surface temperature is maintained within acceptable limits, localized hot spots can be observed in regions corresponding to lower coolant impingement intensity.

FIG. 16 illustrates a manifold design modification for improving surface temperature uniformity. Particularly, FIG. 16 depicts the effect of interchanging the number of inlet flow channels 128 (and thus the number of inlet nozzles 120) and the number of outlet flow channels 130 (and thus the number of outlet nozzles 122), so that the number of inlet flow channels 128 is six and the number of outlet flow channels 130 is five, compared to the design illustrated in FIGS. 6-7. The surface temperature distribution changes noticeably compared to FIG. 15, indicating that inlet-outlet arrangement has a measurable influence on temperature uniformity and, consequently, on the thermal management efficiency of the cooler 102.

In this example, experiments and simulations were performed to investigate the thermos-hydrodynamic performance of the 3D printed cooler 102 shown in FIGS. 6-7, for various flow rate and heat flux boundary conditions. Steady state temperature was recorded for various flow rate and heat flux boundary conditions and compared with the known designs. Numerical simulations are performance to estimate information on surface temperature non-uniformity and flow mal distribution. The experimental and simulation results show that thermal resistance decreases with a rise in coolant flow rate and ˜0.14 K/W is obtained at the maximum coolant flow rate of 2.5 LPM. The thermal performance of the cooler 102 according to this example for a similar range of pumping power is comparable with the high-performing manifold available in the prior art. Surface temperature can be maintained below 80 C, even at a heat flux of 300 W/cm2 when the flow rates exceed 1 LPM. Therefore, the current design cooler 102 is suitable for thermal management of high-power electronics. Flow mal distribution is an inherent challenge and may affect surface temperature distribution. The position of the inlet and outlet nozzles is crucial for a nearly uniform temperature distribution over the impinging surface.

### EXAMPLE 2

In Example 1, there was demonstrated a compact lid-integrable cooler design with distributed impingement and drainage for a heated area of 10 mm×10 mm, and high-heat flux up to 400 W/cm2 using water as working fluid. That design is now scaled to an assembly 300 of a 2.5D interposer package of NVIDIA® V100 chip 302 and a direct-on-chip multi-jet liquid impingement cooler 102 for cooling over the 2.5D interposer package, as illustrated in FIG. 17(a).

Referring to FIG. 17(a)-(b), in the assembly 300, the NVIDIA® V100 chip 302, which was considered for thermal and hydraulic performance testing, has four High Bandwidth Memory (HBM) chips 308 and a central logic 310. The chip 302 is provided on a printed circuit board (PCB) substrate 304, and the cooler 102 interfaces the chip 302 from the top, laying over a stiffener 312 and covered by a lid (cover plate) 306.

The manifold 104 of the cooler 102 was made metallic and lid-compatible, using 3D printing technology, with alternating impinging and draining nozzles 120, 122, and sized to match the dimensions of NVIDIA® V100 chip 302.

FIG. 17(c) shows the cooler 102 in accordance with this example, with dimensions and internal cross-plane structure. Like in Example 1, a small form factor cooler 102 of 5 mm height (size h) is used in this example, by making the inlet and outlet plenums 132, 134 in the same plane and utilizing serpentine partition wall 126 for the working fluid separation. This compactness of the cooling system is crucial for high-density computing environments, especially for 1U server. The orifice diameter is provided 0.5 mm for both inlet and outlet nozzles 120, 122. Two factors were considered during scaling up for 2.5D interposer package cooling, 1) the liquid jet impingement should cover both logic 310 and HBM chips 308, 2) the manifold 104 should rest over the stiffener 312 for mechanical robustness. Also, a higher count of impinging jet was considered for logic chips 310 than HBM 308 due to non-uniform power map distribution and footprint area. The individual HBM 308 is about 8 mm×12 mm, whereas the logic core 310 has a dimension of 26 mm×26 mm. This makes the overall heat transfer area dimensions of the cooler 102 of 26 mm×38 mm, and providing four inlets 116 and four outlets 118.

Metallic manifold 104 offers several competitive advantages, such as high durability, good chemical resistance for variety of working fluids, and excellent mechanical properties for long-term performance. In this example, the 3D printed metallic manifold 104 was made of stainless steel (grade: SS 316L), and manufactured by Protolab®.

The integration of the cooler 102 with V100 chip 302 should ensure structural rigidity, no potential leak sites, and compact packaging solutions. In this example, a chemically compatible Neoprene gasket of thickness 0.5 mm is considered, which provides a more flexible solution for easy mounting and dis-integration of the cooler 102 with the GPU chip 302. Also, it ensures a small gap between the manifold 104 and impinging surface for efficient heat transfer and excellent hydrodynamic performance.

FIG. 18 illustrates a method S400 of assembling the cooler 102 in accordance with this example with the V100 chip 302. This method or any similar method can still be applicable to assembling the cooler 102 of any design disclosed herein with any other electronic device intended to be cooled by the cooler 102.

The assembling method S400 begins with step S402 of mounting the bare GPU chip 302 onto the PCB substrate 304.

The step S402 is followed with a step S404 of careful applying of a rectangular gasket around the stiffener 312 and sealing the gasket to the structure.

After sealing the gasket, at step S406, the cooler 102 is aligned, placed and mounted over the stiffener 312. In some preferable embodiments, solder or epoxy can be used for permanent sealing between the manifold 104 and the stiffener 312 of the 2.5D interposer package.

Step S406 is followed by step S408 of mechanically pressurizing the manifold 104 with the top cover plate 306 and screw arrangement to ensure mechanical robustness and leak proof operation, and final assembly with fluid connections. A good mechanical compression and leak-proof sealing are provided by using the top cover 306 made of a stainless-steel plate of thickness 3 mm, and four M3 screws. This also ensures consistent pressure distribution over the manifold 104.

The assembly 300 of the cooler 102 and the V100 chip 302 in this example was further mounted onto a 1U server to provide the required GPU load during the testing (the right section of FIG. 18 shows the fully mounted cooling system installed in the server, demonstrating the practical implementation of the microjet cooling solution for high-power AI chips).

The thermo-hydrodynamic performance was studied for various V100 GPU power and flow rates with a dielectric working fluid being R1233zd(E) under two-phase jet cooling conditions. Two-phase operation of the dielectric working fluid R1233zd(E) needs precise control of flow-loop operating conditions during experiments. A flow-loop similar to the experimental setup 200 used in Example 1 was used to provide desired flow rate, inlet temperature of coolant and saturation conditions for the assembly 300. Several peripheral instruments such as thermocouples, pressure transducer, DAQ, and computers were used with the assembly 300 to record and monitor temperature, pressure, and flow rates. NVIDIA® V100 GPU 302 has total design power (TDP) of 300 W. A bypass loop provided fine flow control, and a 2 μm particulate filter removed contaminants. Upstream, a liquid-to-liquid heat exchanger regulated the inlet temperature. The required power to the GPU chip 302 was provided by CUDA stress test. Subsequent temperature and power were recorded during the test. Additional visualization windows were provided at the working fluid outlet to check the boiling behavior. The experiments were conducted at a subcooling of 1° C. to the saturation conditions of 37.5° C.

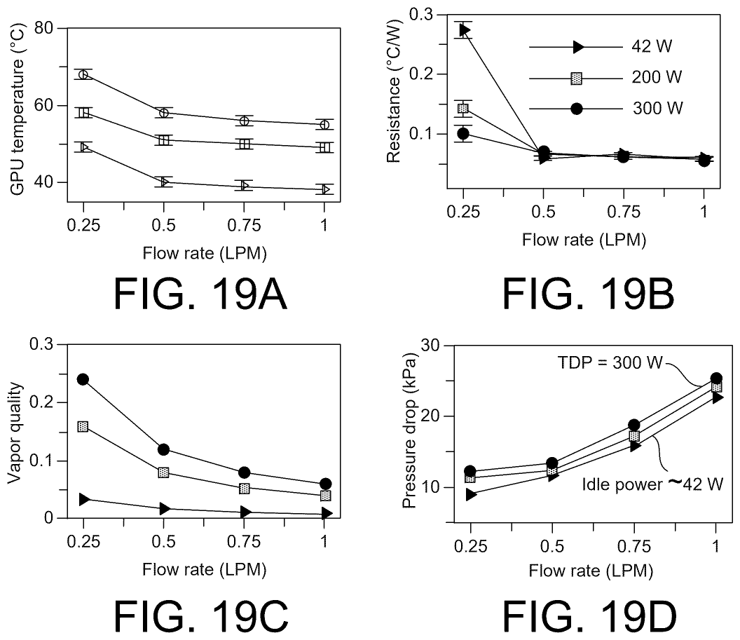

FIG. 19 illustrates charts of thermal performance characterization of the manifold design shown in FIGS. 17-18. Thermal performance of the cooler 102 was tested for various experimental conditions. Particularly, four metrics were used including: 1) steady-state GPU temperature (° C.) (see FIG. 19(a)), 2) thermal resistance (° C./W) (see FIG. 19(b)), 3) exit vapor quality (see FIG. 19(c)), 4) pressure drop (kPa) across the manifold 104 (see FIG. 19(d)) for various GPU power level and coolant flow rates (LPM). In this two-phase operation, the coolant flow rate varies from 0.25 LPM to 1 LPM, and for a maximum GPU power of 300 W. It is noted that GPU power is a combined contribution of both logic and HBM power, and there was no provision to control individual power maps. The embedded temperature sensor in the NVIDIA® V100 chip 302 is reported as the GPU temperature and subsequently used for thermal performance measurement.

As shown in FIG. 19(a), steady-state GPU temperature is plotted for three different power loads, i.e., i) idle conditions, nearly 42 W, ii) 200 W and iii) thermal design power, 300 W. As evident, the temperature increases for all flow rates with a rise in GPU load. The operating temperature is always measured below 70° C., even at a low coolant flow rate of 0.25 LPM and maximum power of 300 W. Also, the operating temperature is measured to be about 55° C. at a flow rate of 1 LPM for the same GPU power. The reliable temperature limit for NVIDIA® V100 chips is ≤82° C. This excellent thermal performance of the current manifold design achieves an about 27° C. lower operating temperature than reliable temperature limit, even at the TDP power. Also, the relative sensitivity to the coolant flow rate on operating temperature decreases above the flow rate of 0.5 LPM. This observation is well reported in the prior art of two-phase liquid jet impingement and flow boiling configuration. In the idle conditions, GPU draws power to perform base-level system operations, without performing useful computation work. Therefore, the cooling strategy must account for these parasitic losses and try to minimize overall pumping power. These experimentally obtained results emphasize the efficacy of the multi-jet impingement cooler design in accordance with the present disclosure for high-performance GPU applications, where there is only 16° C. rise in temperature even though the heat load increased to 300 W.

As shown in FIG. 19(b), the thermal resistance value of about 0.057° C./W is achieved at a range of the flow rates of 0.5-1 LPM. However, at a lower flow rate of 0.25 LPM, the thermal resistance is measured to be higher, demonstrating an optimal flow rate condition. The relative insensitivity of thermal resistance on flow rate and GPU power is clearly seen above a flow rate of 0.5 LPM. By extrapolating this thermal resistance value to the higher power level, a maximum of about 890 W can be dissipated, and still the operating temperature can be maintained below 82° C. However, the dry-out must be investigated for different flow rates prior operating at such high GPU power level.

Vapor quality is another parameter of interest, and it is a measure of mass fraction of vapor at the outlet of the manifold 104. Higher vapor quality indicates a utilization of latent heat of coolant and ensures a lower coolant flow rate requirement. The vapor quality is higher at the TDP power level, reaching ˜0.24 at 0.25 LPM. It is evident that vapor quality decreases with an increase in the coolant flow rate, and the results follow a similar trend, as shown in FIG. 19(c). It is desired to operate at a higher vapor quality, but the potential risk of dry-out/flow instability increases.

The pressure drop across the manifold 104 is plotted for various boundary conditions, and as evident it increases with a rise in the flow rate. As can be seen in FIG. 19(d), the maximum pressure drop is measured to be about 25 kPa for the maximum flow rate of 1 LPM and 300 W power. Also, it marginally rises with a supply of GPU power due to vapor bubble generations during two-phase operations.

In the real-life scenario, power loads to the GPU can fluctuate due to dynamic workloads. Therefore, it demands efficient thermal management solutions that maintain a nearly uniform operating temperature, and below the operational reliability limit.

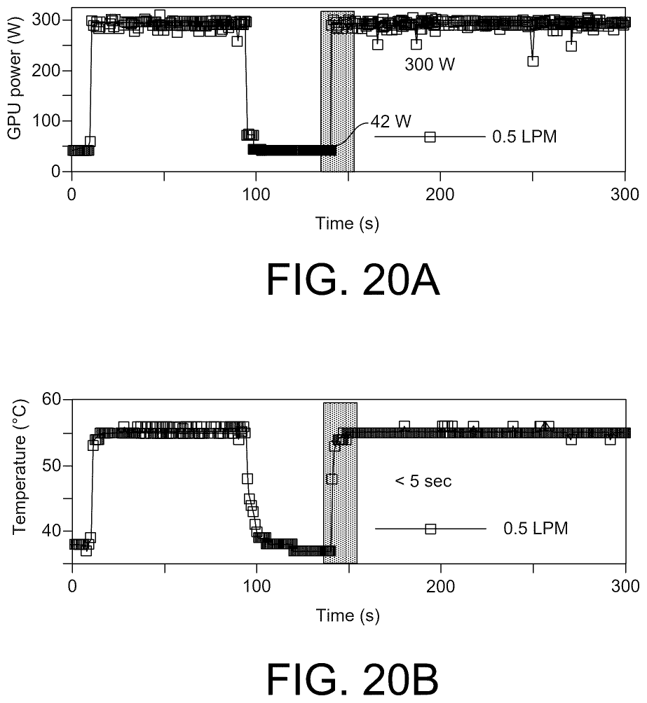

FIG. 20 shows the transient GPU power and temperature under dynamic load conditions with step power rise and shut down for a fixed flow rate of 0.5 LPM for the cooler assembly as shown in FIGS. 17-18. Using CUDA stress test, the power to the GPU is suddenly increased from idle operation (about 42 W) to a maximum GPU power of 300 W and vice-versa (see FIG. 20(a)). The corresponding transient temperature is plotted in FIG. 20(b). It is seen that GPU temperature stabilizes around 55° C. and 38° C. for a power level of 300 W and idle power, respectively. Time required to rise in GPU temperature occurs in <2 seconds, and it gradually reaches steady state within <5 seconds. This demonstrates a highly responsive thermal behavior of current cooling system. No temperature overshoot is observed during transient operation, which highlights the thermal stability and a small thermal inertia. The excellent transient response with thermal performance validates the cooling solutions suitability for dynamic power environments, where the GPU load is often frequent and unpredictable.

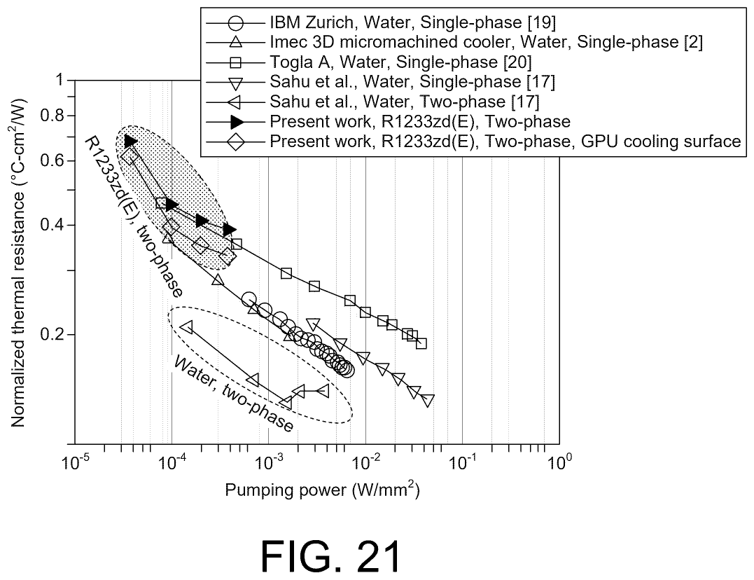

FIG. 21 shows a chart with thermo-hydraulic evaluation of the cooler design using R1233zd(E) as the working fluid against other known design benchmarks by comparing normalized thermal resistance and pumping power. The overall performance is found to be comparable, with a slightly higher thermal resistance, while the pumping power remains in a similar range. Notably, the cooler design in accordance with the present disclosure supports lid-compatible and direct-on-chip configurations and was tested using actual GPU power, unlike prior studies that relied on simulated heater setups. The presence of HBM 308 increases the operating temperature of the logic components due to thermal crosstalk through the silicon interposer. In FIG. 21, the normalized thermal resistance, referenced to the working fluid cooling surface temperature on the top surface of the GPU silicon, is derived using a 1-D thermal resistance network estimation. This estimation considers a value of 0.05 K·cm²/W for the silicon die and 0.01 K·cm²/W for the back end of line (BEOL) based on prior art design data.

Although the thermal resistance of two-phase R1233zd(E) cooling is about an order of magnitude higher than that of two-phase water cooling, attributable to water's superior working fluid properties, R1233zd(E) offers excellent dielectric characteristics and compatibility with chip packaging materials, making it a more reliable cooling solution for direct on chip cooling.

Accordingly, a lid-compatible liquid jet impingement with direct-on-chip cooling approach was proposed in this example for a 2.5D interposer architecture. Real-time high-power GPU cooling using a compact metallic cooler 102 in accordance with the present disclosure was performed under controlled experimental conditions with flow rate varies from 0.25-1 LPM, and GPU power, with a maximum of 300 W. First, the lid-compatible manifold was scaled to match the dimensions of actual NVIDIA V100 GPU, ensuring liquid jet covers the heat dissipating components. As a result of the testing, the system level integration of the lid-compatible design successfully demonstrated a mechanically robust and leak-free design. The thermal performance of the cooler was tested by measuring steady-state temperature, thermal resistance, pressure drop and exit vapor quality, and a lower operating chip surface temperature was always maintained even though the GPU load reached 300 W, as the flow rate exceeded 0.5 LPM. A very low thermal resistance was obtained, measuring about 0.057° C./W. Also, exit vapor quality of 0.24 was achieved without reaching the dry-out conditions, demonstrating a good latent heat utilization in two-phase operation. Also, the response to step change in power was demonstrated to be very fast, and without any temperature shoot, making it suitable and practical solution for dynamic power loading. The design in accordance with the present disclosure can be effectively used for higher GPU power, as high as over 890 W by performing a prior study on dry-out conditions at various power maps and flow rates. The lower thermal resistance along with a lower operating temperature demonstrates the excellent thermal performance of the manifold design in accordance with the present disclosure. Overall, this metallic manifold design, particularly with compact form-factor, can provide excellent mechanical robustness, efficient heat transfer, and scalable chip-scale cooling solutions for high-power AI chip applications.

As illustrated above, the cooler 102 in accordance with the present disclosure, which utilizes multi-jet liquid impingement with alternating drainage, demonstrates an efficient heat transfer with provision of a lid-compatible solution for high-power AI chips.

While examples, one or more representative embodiments and specific forms of the disclosure have been illustrated and described in detail in the drawings and foregoing description, the same is to be considered as illustrative and not restrictive or limiting. The description of particular features in one embodiment does not imply that those particular features are necessarily limited to that one embodiment. Some or all of the features of one embodiment can be used in combination with some or all of the features of other embodiments as would be understood by one of ordinary skill in the art, whether or not explicitly described as such. One or more exemplary embodiments have been shown and described, and all changes and modifications that come within the spirit of the disclosure are desired to be protected.

I/We claim:

1. A system for cooling electronic devices, comprising:
a manifold configured to be thermally coupled to an electronic device;
a plurality of inlet nozzles;
a plurality of outlet nozzles; and
at least one partition wall defining a serpentine working fluid flow path in the manifold;
wherein the inlet nozzles are configured to direct in jets a working fluid delivered to the manifold for impingement cooling of the electronic device; and the outlet nozzles are configured to remove a heated working fluid from the manifold.

2. The system of claim 1, wherein the inlet nozzles and the outlet nozzles are arranged in a lateral alternating pattern.

3. The system of claim 1, further comprising at least one inlet flow channel and at least one outlet flow channel.

4. The system of claim 3, wherein the at least one partition wall is configured to separate the at least one inlet flow channel and the at least one outlet flow channel.

5. The system of claim 4, wherein the at least one inlet flow channel and the at least one outlet flow channel are alternately arranged across the width of the manifold.

6. The system of claim 5, wherein the inlet nozzles are fluidly connected to the at least one inlet flow channel, and the outlet nozzles are fluidly connected to the at least one outlet flow channel.

7. The system of claim 6, wherein the inlet nozzles are arranged perpendicularly to the at least one inlet flow channel, and the outlet nozzles are arranged perpendicularly to the at least one outlet flow channel.

8. The system of claim 1, wherein the inlet nozzles and the outlet nozzles are arranged in a staggered pattern across the width of the manifold.

9. The system of claim 1, further comprising one or more inlets for delivering the working fluid into the manifold and one or more outlets for removing the heated working fluid from the manifold, wherein the one or more inlets are fluidly connected to the inlet nozzles, and the one or more outlets are fluidly connected to the outlet nozzles.

10. The system of claim 1, wherein the manifold is assembled with the electronic device.

11. The system of claim 10, wherein the assembly is a stacked assembly comprising a substrate, the electronic device supported on the substrate, and the manifold attached to or integrated in a lid attached to the substrate, such that a heat transfer area of the manifold interfaces with a heat-generating surface of the electronic device.

12. The system of claim 1, wherein the manifold has a total height of 5 mm or less.

13. The system of claim 1, wherein the size of each inlet nozzle of the plurality of inlet nozzles is bigger than the size of each outlet nozzle of the plurality of outlet nozzles.

14. The system of claim 1, wherein the working fluid is a coolant selected from water and a dielectric working fluid.

15. The system of claim 1, wherein the system is configured to be attached to the electronic device without intermediate thermal interface materials, by direct interfacing of a heat transfer area of the manifold with the electronic device.

16. A method of cooling an electronic device using a manifold configured to be thermally coupled to the electronic device by a heat transfer area of the manifold, the heat transfer area comprising inlet nozzles and outlet nozzles laterally arranged in an alternating pattern, and at least one partition wall defining a serpentine flow path with separated cool and heated coolant flow channels, the method comprising:
positioning the manifold over the electronic device;
introducing the coolant through the inlet nozzles to create impinging coolant jets directed towards the electronic device for cooling the electronic device;
collecting a heated coolant through the outlet nozzles; and
maintaining a surface temperature of the electronic device below 80° C. under operating heat flux conditions.

17. The method of claim 16, wherein the coolant is delivered to the manifold through at least one inlet fluidly connected to the inlet nozzles, and the heated coolant is removed from the manifold through at least one outlet fluidly connected to the outlet nozzles.

18. The method of claim 16, further comprising controlling a coolant flow rate between 0.5 LPM and 2.5 LPM.

19. The method of claim 16, wherein the manifold is attached to the electronic device without intermediate thermal interface materials by direct interfacing with the electronic device.

20. A multi-jet liquid impingement cooler for microelectronic devices, comprising a manifold having an integrated serpentine wall structure, and alternating feeding and draining nozzles, wherein the integrated serpentine wall structure separates cool and heated coolant flow channels, wherein the feeding nozzles are configured to direct in jets a cool coolant, which is delivered to the manifold, toward the microelectronic device for impingement cooling of the microelectronic device, and wherein the draining nozzles are configured to remove the heated coolant from the manifold.
